(19) United States
(12) Patent Application Publication
(10) Pub. No.: US 2014/0248733 A1
(43) Pub. Date: Sep. 4, 2014

(54) METHOD OF MANUFACTURING PHOTOELECTRIC CONVERSION DEVICE

(71) Applicant: SHARP KABUSHIKI KAISHA,, Osaka-shi, Osaka (JP)

(72) Inventors: Shinya Honda, Osaka-shi (JP); Yoshiyuki Nasuno, Osaka-shi (JP); Takashi Yamada, Osaka-shi (JP); Kazuhito Nishimura, Osaka-shi (JP)

(21) Appl. No.: 14/349,936

(22) PCT Filed: Sep. 27, 2012
(86) PCT No.: PCT/JP2012/074848

§ 371 Date: Apr. 4, 2014

(30) Foreign Application Priority Data
Oct. 7, 2011 (JP) 2011-222874

(51) Int. Cl. H01L 21/66; H01L 31/18

(52) U.S. Cl. CPC H01L 22/26; H01L 31/18
USPC 438/57

(57) ABSTRACT

The present invention provides a method of manufacturing a photoelectric conversion device for forming a semiconductor layer on a substrate by the plasma CVD method. The method includes a first plasma processing step in which a processing temperature reaches a first temperature; a second plasma processing step in which the processing temperature reaches a second temperature; a temperature regulating step of lowering the processing temperature to a third temperature lower than the first temperature and the second temperature after the first plasma processing step and before the second plasma processing step; and a temperature raising step of raising the processing temperature from the third temperature to the second temperature. The first plasma processing step, the temperature regulating step, the temperature raising step, and the second plasma processing step are carried out within the same reaction chamber.

### TECHNICAL FIELD

The present invention relates to a method of manufacturing a photoelectric conversion device formed by stacking a plurality of photoelectric conversion bodies.

### BACKGROUND ART

In recent years, attention has been paid to a thin-film photoelectric conversion element formed by the plasma CVD method using gas as a raw material. Examples of such a thin-film photoelectric conversion element include a silicon-based thin-film photoelectric conversion element made of a silicon-based thin film, a thin-film photoelectric conversion element made of a CIS (CuInSe₂) compound or a CIGS (Cu (In, Ga) Se₂) compound, and the like. Development and production volume increase for such a thin-film photoelectric conversion element are being promoted. A significant feature of these photoelectric conversion elements lies in that a semiconductor layer or a metal electrode film is stacked on an inexpensive substrate having a relatively large area using a formation apparatus such as a plasma CVD apparatus or a sputtering apparatus, and then, the photoelectric conversion element fabricated on the same substrate is separated and connected by laser patterning, thereby allowing both of cost reduction and enhanced performance of the photoelectric conversion element. In such a manufacturing process, however, the cost for manufacturing the photoelectric conversion element is increased due to an increase in cost for a semiconductor layer manufacturing apparatus represented by the plasma CVD apparatus that is a basic apparatus for manufacturing a device. This is one of obstacles to widespread proliferation of such a photoelectric conversion element.

The apparatus for manufacturing a photoelectric conversion element has been conventionally employed in a in-line system in which a plurality of film formation chambers (each of which is also referred to as a chamber; the same shall apply hereinafter) are linearly coupled, or in a multi-chamber system in which an intermediate chamber is provided at the center, around which a plurality of film formation chambers are arranged. In the in-line system, the flow line for conveying a substrate extends linearly. Accordingly, even when it becomes necessary to perform partial maintenance, the entire apparatus needs to be stopped. For example, a plurality of film formation chambers are included that are used to form an i-type silicon photoelectric conversion layer for which maintenance is needed most. Accordingly, there is a disadvantage that the entire production line is stopped even though maintenance is required for only one film formation chamber in which an i-type silicon photoelectric conversion layer is formed.

On the other hand, according to the multi-chamber system, the substrate on which a film is to be formed is transferred through the intermediate chamber to each film formation chamber. A movable partition capable of maintaining airtightness is provided between each film formation chamber and the intermediate chamber. Accordingly, even when a failure occurs in one film formation chamber, other film formation chambers can be used. Thus, production is not entirely stopped. However, since the manufacturing apparatus in this multi-chamber system includes a plurality of substrate flow lines through the intermediate chamber, it is inevitable that the mechanical structure in the intermediate chamber becomes complicated. For example, the mechanism for transferring the substrate while maintaining airtightness between the intermediate chamber and each film formation chamber becomes complicated and expensive. There also occurs a problem that the number of film formation chambers arranged around the intermediate chamber is limited in terms of space.

In consideration of the above-described problems, Japanese Patent Laying-Open No. 2000-252496 (PTD 1) discloses a method of manufacturing a thin-film photoelectric conversion device having an amorphous-type photoelectric conversion unit and a crystalline-type photoelectric conversion unit stacked one on top of the other. By this method, a p-type semiconductor layer, an i-type crystalline silicon series and an n-type semiconductor layer in the crystalline-type photoelectric conversion unit each are formed within the same plasma CVD reaction chamber.

Furthermore, “Reduction of the boron cross-contamination for plasma deposition of p-i-n devices in a single-chamber large area radio-frequency reactor” (Thin Solid Films Volume 468; pages 222 to 225) by J. Ballutauda et al. (NPD 1) proposes that ammonia flushing should be carried out in order to avoid the influence of p-type impurities produced when different semiconductor layers are formed within the same reaction chamber. Furthermore, Japanese Patent Laying-Open No. 2008-166366 (PTD 2) proposes that, when a photoelectric conversion element having a p-type semiconductor layer, an i-type semiconductor layer and an n-type semiconductor layer is formed within the same reaction chamber by the plasma CVD method, the step of removing impurities within the reaction chamber using substitute gas should be performed before forming the semiconductor layers, in order to form semiconductor layers of good quality.

### CITATION LIST

### Patent Document

PTD 1: Japanese Patent Laying-Open No. 2000-252496
PTD 2: Japanese Patent Laying-Open No. 2008-166366

### Non Patent Document

NPD 1: “Reduction of the boron cross-contamination for plasma deposition of p-i-n devices in a single-chamber large area radio-frequency reactor” (Thin Solid Films Volume 468; pages 222 to 225) by J. Ballutaud et al.

### SUMMARY OF INVENTION

### Technical Problem

However, according to the method of forming a plurality of types of semiconductor layers having different conductivity types within the same reaction chamber by the plasma CVD method, there is a problem that it is difficult to achieve a photoelectric conversion device having excellent photoelectric conversion characteristics. An object of the present invention is to provide a method of manufacturing a photoelectric conversion device having excellent photoelectric conversion characteristics at low cost and with high efficiency by carrying out the plasma CVD method within the same reaction chamber.

### Solution to Problem

As a result of dedicated study, the inventors of the present invention found that plasma processing continuously carried out within the same reaction chamber leads to a partial heating of the inside of the reaction chamber and a product to be processed due to radio-frequency discharge (RF discharge), with the result that the in-plane temperature of the product to be processed becomes nonuniform, thereby increasing the in-plane non-uniformity of the photoelectric conversion characteristics in the product to be processed. Thus, the inventors of the present invention achieved the present invention.

The present invention is a method of manufacturing a photoelectric conversion device for forming a semiconductor layer on a substrate by a plasma CVD method. The method includes a first plasma processing step in which a processing temperature reaches a first temperature; a second plasma processing step in which the processing temperature reaches a second temperature; and a temperature regulating step of lowering the processing temperature to a third temperature lower than the first temperature and the second temperature after the first plasma processing step and before the second plasma processing step. The first plasma processing step, the temperature regulating step and the second plasma processing step are carried out within the same reaction chamber. The “processing temperature” used herein is the temperature of the product to be processed when there is a product to be processed. In the case where the product to be processed is supported by a support body, the temperature of the support body can be regarded a temperature of the product to be processed. Furthermore, in the case where there is no product to be processed, the processing temperature is regarded as a temperature corresponding to the temperature of the product to be processed at the time when there is the product to be processed. In the case where there is a support body for the product to be processed, the processing temperature is regarded as a temperature of this support body.

One embodiment of the above-described present invention is a method of manufacturing a photoelectric conversion device formed by stacking a substrate, a first photoelectric conversion body and a second photoelectric conversion body in this order. The first photoelectric conversion body is stacked in the first plasma processing step, and the second photoelectric conversion body is stacked in the second plasma processing step. According to the present embodiment, the first photoelectric conversion body can be produced to include an amorphous silicon-based photoelectric conversion layer, and the second photoelectric conversion body can be produced to include a microcrystalline silicon-based photoelectric conversion layer.

In the above-described present invention, the third temperature preferably has a value, as a centigrade temperature, obtained by multiplying a centigrade temperature value of the second temperature by 0.7 to 0.99.

According to the above-described present invention, preferably, the processing temperature is regulated by using heating means for heating an inside of the reaction chamber and/or cooling means for cooling the inside of the reaction chamber. “Heating an inside of the reaction chamber” and “cooling the inside of the reaction chamber” used herein only have to heat or cool the product to be processed, if any, and represents the manner of heating or cooling the support body of the product to be processed, for example.

According to one embodiment of the above-described present invention, the first plasma processing step includes a time during which the cooling means is not used. Furthermore, according to one embodiment of the above-described present invention, the second plasma processing step includes a time during which the cooling means is not used.

The above-described present invention includes a temperature raising step of raising the processing temperature from the third temperature to the second temperature after the temperature regulating step. At least a part of this temperature raising step may be carried out during the second plasma processing step. In this case, preferably, the processing temperature is regulated by using the heating means for heating the inside of the reaction chamber and/or the cooling means for cooling the inside of the reaction chamber. According to one embodiment of the present invention, the cooling means is not used in the temperature raising step.

The above-described present invention may include a temperature maintaining step of maintaining the processing temperature at the second temperature for a certain period of time before the second plasma processing step. In this case, preferably, the processing temperature is regulated by using the heating means for heating the inside of the reaction chamber and/or the cooling means for cooling the inside of the reaction chamber. According to one embodiment of the present invention, the cooling means is not used in the temperature maintaining step. In addition, in the present specification, the expression of maintaining the processing temperature at a prescribed temperature means that the processing temperature is maintained at a temperature having a value, as a centigrade temperature, that falls within the range of ±10% of the centigrade temperature value of the prescribed temperature.

The above-described present invention may include a third plasma processing step in which the processing temperature reaches a fourth temperature different from the second temperature after the second plasma processing step. In this case, the first plasma processing step, the temperature regulating step, the second plasma processing step, and the third plasma processing step are carried out within the same reaction chamber. For example, the inside of the reaction chamber can be cleaned by the third plasma processing step.

In this case, preferably, the processing temperature is regulated by using the heating means for heating the inside of the reaction chamber and/or the cooling means for cooling the inside of the reaction chamber. According to one embodiment of the present invention, the cooling means is used in the third plasma processing step. Furthermore, according to one embodiment of the present invention, the third plasma processing step includes a time during which the cooling means is not used.

According to one embodiment of the above-described present invention, the first plasma processing step, the temperature regulating step and the second plasma processing step are repeatedly carried out within the same reaction chamber.

### Advantageous Effects of Invention

According to the method of manufacturing a photoelectric conversion device of the present invention, semiconductor layers are formed within the same reaction chamber, so that a photoelectric conversion device having excellent photoelectric conversion characteristics can be manufactured at low cost and with high efficiency.

### BRIEF DESCRIPTION OF DRAWINGS

FIG. 1 is a flowchart schematically showing a manufacturing method according to the present invention.

FIG. 2 is a cross-sectional view schematically showing an example of the configuration of a plasma CVD device used in the manufacturing method according to the present invention.

FIG. 3 is a cross-sectional view schematically showing an example of the configuration of a photoelectric conversion device manufactured by the manufacturing method according to the present invention.

FIG. 4 is a graph showing changes in a control temperature and a processing temperature in Example 1a.

FIG. 5 is a graph showing changes in a control temperature and a processing temperature in Example 1b.

FIG. 6 is a graph showing changes in a control temperature and a processing temperature in Example 2.

FIG. 7 is a graph showing the relation between the third temperature and each of the output of the photoelectric conversion device and the time required for forming the second photoelectric conversion body.

FIG. 8 is a graph showing changes in a control temperature and a processing temperature in Example 3.

FIG. 9 is a graph showing changes in a control temperature and a processing temperature in Example 4.

FIG. 10 is a graph showing changes in a control temperature and a processing temperature in Example 5.

FIG. 11 is a graph showing changes in a control temperature and a processing temperature in Example 6.

### DESCRIPTION OF EMBODIMENTS

[Method of Manufacturing Photoelectric Conversion Device]

The present invention provides a method of manufacturing a photoelectric conversion device for forming a semiconductor layer on a substrate by the plasma CVD method. The manufacturing method according to the present invention will be hereinafter described in detail with reference to the accompanying drawings.

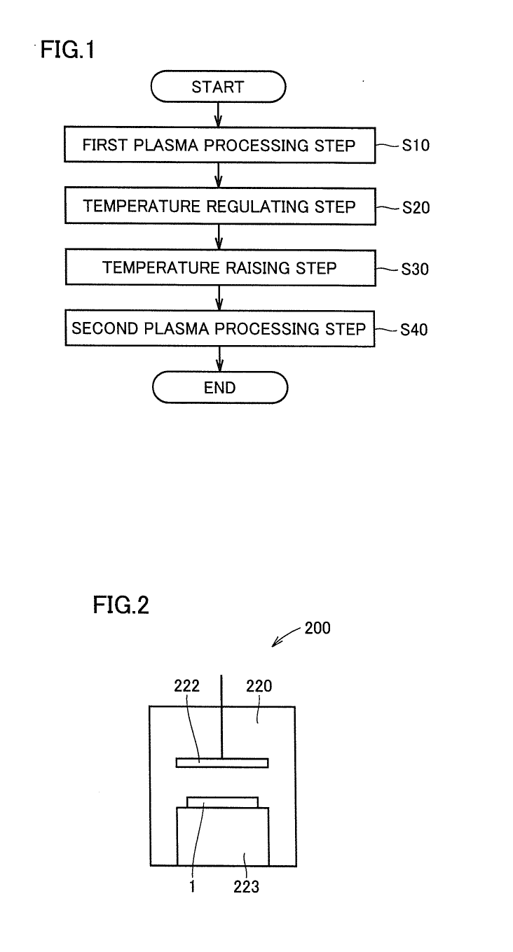

FIG. 1 is a flowchart schematically showing a manufacturing method according to the present invention. As shown in FIG. 1, the manufacturing method according to the present invention includes a first plasma processing step (S10), a temperature regulating step (S20), a temperature raising step (S30), and a second plasma processing step (S40). The temperature raising step (S30) may be carried out before the second plasma processing step (S40), may be carried out during the second plasma processing step (S40), or may be carried out before and during the second plasma processing step (S40). However, when at least a part of the temperature raising step (S30) is carried out during the second plasma processing step (S40), the total time period of the process is shortened as compared with the case where the temperature raising step (S30) is carried out before the second plasma processing step (S40). FIG. 1 shows the case where the temperature raising step (S30) is carried out before the second plasma processing step (S40). In the manufacturing method according to the present invention, each step from the first plasma processing step (S10) to the second plasma processing step (S40) is carried out within the same reaction chamber. In other words, the first plasma processing step (S10), the temperature regulating step (S20), the temperature raising step (S30), and the second plasma processing step (S40) shown in FIG. 1 are carried out within the same reaction chamber.

A semiconductor layer is formed on a substrate by the first plasma processing step (S10) and the second plasma processing step (S40). One semiconductor layer may be formed or a plurality of semiconductor layers may be formed by the first plasma processing step (S10) and the second plasma processing step (S40).

In the first plasma processing step (S10), the processing temperature is controlled so as to reach the first temperature (T1). In the second plasma processing step (S40), the processing temperature is controlled so as to reach the second temperature (T2). In the temperature regulating step (S20), the processing temperature is lowered to the third temperature (T3) lower than the first temperature (T1) and the second temperature (T2). In the temperature raising step (S30), the processing temperature is raised from the third temperature (T3) to the second temperature (T2).

The “processing temperature” used herein means the temperature of the substrate support body supporting a substrate within the reaction chamber, and for example, means the temperature of the anode in the case where the substrate is placed on the anode and supported by this anode. Furthermore, the “processing temperature” means the temperature of the support body that is to support a substrate also when the substrate is not disposed.

In this way, the temperature regulating step (S20) is included after the first plasma processing step (S10) and before the second plasma processing step (S40), thereby improving the non-uniformity of the in-plane temperature of the product to be processed in the second plasma processing step (S40). Thus, it becomes possible to provide a photoelectric conversion device having photoelectric conversion characteristics with improved in-plane non-uniformity. It is preferable that third temperature T3 is a temperature having a value, as a centigrade temperature, obtained by multiplying the centigrade temperature value of second temperature T2 by 0.7 to 0.99 since this can achieve excellent photoelectric conversion characteristics and excellent control efficiency. Furthermore, in the present invention, a more significant effect of improving the photoelectric conversion characteristics can be achieved when second temperature (T2) is lower than first temperature (T1).

In the present embodiment, the first plasma processing step (S10), the temperature regulating step (S20), the temperature raising step (S30), and the second plasma processing step (S40) are carried out within the same reaction chamber to form a stacked body used for a photoelectric conversion device, and thereafter, the first plasma processing step (S10), the temperature regulating step (S20), the temperature raising step (S30), and the second plasma processing step (S40) are carried out again within the same reaction chamber, to thereby allow formation of another stacked body. The process within the same reaction chamber including the first plasma processing step (S10), the temperature regulating step (S20), the temperature raising step (S30), and the second plasma processing step (S40) can be carried out repeatedly any number of times.

[Plasma CVD Device]

FIG. 2 is a cross-sectional view schematically showing an example of the configuration of a plasma CVD device used in the manufacturing method according to the present invention. A plasma CVD device 200 shown in FIG. 2 has a configuration in which a cathode 222 and an anode 223 are arranged within a reaction chamber 220. Film formation in plasma CVD device 200 is carried out by placing a product to be processed (a substrate) on anode 223 and applying an alternating-current (AC) voltage between cathode 222 and anode 223. When the manufacturing method of the present invention is performed using plasma CVD device 200, the steps from the first plasma processing step (S10) to the second plasma processing step (S40) are carried out within the same reaction chamber 220. Heating means (not shown) for heating anode 223 and cooling means (not shown) for cooling anode 223 are provided within reaction chamber 220.

### First Embodiment

### Photoelectric Conversion Device

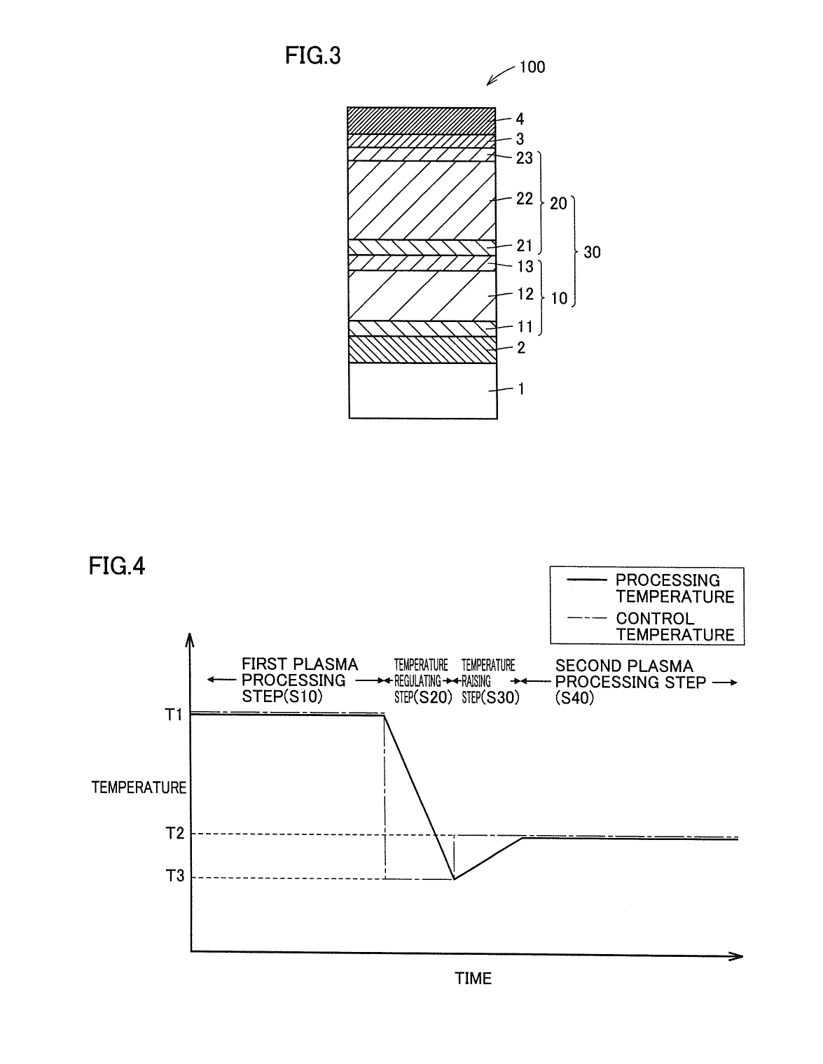

FIG. 3 is a cross-sectional view schematically showing the configuration of a photoelectric conversion device manufactured by the manufacturing method according to the present embodiment. A photoelectric conversion device 100 shown in FIG. 3 includes a first photoelectric conversion body 10, a second photoelectric conversion body 20, a conductive film 3, and a metal electrode 4 on a transparent conductive film 2 formed on a substrate 1. First photoelectric conversion body 10 is an amorphous pin structure stacked body formed by stacking a first p-type semiconductor layer 11, an i-type amorphous silicon-based photoelectric conversion layer 12 and a first n-type semiconductor layer 13 in this order. Second photoelectric conversion body 20 is a microcrystalline pin structure stacked body formed by stacking a second p-type semiconductor layer 21, an i-type microcrystalline silicon-based photoelectric conversion layer 22 and a second n-type semiconductor layer 23 in this order. The term of “microcrystalline” used in the present application means the state partially including an amorphous state.

Materials of first photoelectric conversion body 10 and second photoelectric conversion body 20 are not particularly limited as long as they have photoelectric conversion characteristics. For example, it is preferable to use Si, SiGe, SiC or the like that is a silicon-based semiconductor. Amorphous pin structure stacked body 10 is particularly preferably a stacked body having a p-i-n type structure of a hydrogenated amorphous silicon-based semiconductor (a-Si:H). Microcrystalline pin structure stacked body 20 is particularly preferably a stacked body having a p-i-n type structure of a hydrogenated microcrystalline silicon-based semiconductor (μc-Si:H).

Photoelectric conversion device 100 shown in FIG. 3 receives light incident from the substrate 1 side. In this photoelectric conversion device 100, short-wavelength light can be efficiently absorbed by amorphous pin structure stacked body 10 while long-wavelength light can be absorbed by microcrystalline pin structure stacked body 20, so that enhanced photoelectric conversion efficiency can be implemented. Furthermore, since the in-plane non-uniformity of the photoelectric conversion efficiency in microcrystalline pin structure stacked body 20 can be improved by the manufacturing method according to the present invention, excellent photoelectric conversion characteristics are achieved.

<Manufacturing Method>

In the present embodiment, the steps from the first plasma processing step (S10) to the second plasma processing step (S40) are carried out using the plasma CVD device shown in FIG. 2. In the first plasma processing step (S10), first p-type semiconductor layer 11, i-type amorphous silicon-based photoelectric conversion layer 12 and first n-type semiconductor layer 13 are sequentially stacked to form first photoelectric conversion body (amorphous pin structure stacked body) 10 having a p-i-n type structure. Then, in the second plasma processing step (S40), second p-type semiconductor layer 21, i-type microcrystalline silicon-based photoelectric conversion layer 22 and second n-type semiconductor layer 23 are sequentially stacked to form second photoelectric conversion body (microcrystalline pin structure stacked body) 20 having a p-i-n type structure.

First, transparent conductive film 2 is formed on substrate 1, for example, by the vacuum evaporation method or the sputtering method. The substrate used herein can be a glass substrate and a resin substrate made of polyimide or the like, which exhibit heat resistance and translucency in film formation of a semiconductor layer by the plasma CVD method. Furthermore, a transparent conductive film made of at least one or more types of oxides selected from SnO₂, ITO and ZnO can be used as transparent conductive film 2.

Substrate 1 having transparent conductive film 2 formed thereon is placed on anode 223 within reaction chamber 220 of plasma CVD device 200, and the steps from the first plasma processing step (S10) to the second plasma processing step (S40) are carried out. In the first plasma processing step (S10), raw material gas is introduced into reaction chamber 220, and an AC voltage is applied between cathode 222 and anode 223, to sequentially form first p-type semiconductor layer 11, i-type amorphous silicon-based photoelectric conversion layer 12 and first n-type semiconductor layer 13 by the plasma CVD method, thereby forming first photoelectric conversion body 10. In the second plasma processing step (S40), raw material gas is introduced into reaction chamber 220, and an AC voltage is applied between cathode 222 and anode 223 to sequentially form second p-type semiconductor layer 21, i-type microcrystalline silicon-based photoelectric conversion layer 22 and second n-type semiconductor layer 23 by the plasma CVD method on first photoelectric conversion body 10, thereby forming second photoelectric conversion body 20.

Then, conductive film 3 made of ITO, ZnO or the like and a metal electrode 4 made of aluminum, silver or the like are formed by the sputtering method, the evaporation method or the like on second photoelectric conversion body 20 that is a stacked body produced as described above, thereby manufacturing photoelectric conversion device 100.

It is preferable that diluent gas containing silane-based gas and hydrogen gas is included as raw material gas introduced into reaction chamber 220 in the first plasma processing step (S10) and the second plasma processing step (S40). Furthermore, doping materials for the conductivity-type semiconductor layer to be used can be boron, aluminum and the like for a p-type, and phosphorus and the like for an n-type, for example.

The film formation condition in the first plasma processing step (S10) can be established such that, for example, the pressure is set at 200 Pa or higher and 3000 Pa or lower, and the power density per electrode unit is set at 0.01 W/cm² or higher and 0.3 W/cm² or lower. The film formation condition in the second plasma processing step (S40) can be established such that, for example, the pressure is set at 600 Pa or higher and 3000 Pa or lower, and the power density per electrode unit area is set at 0.05 W/cm² or higher and 0.3 W/cm² or lower.

Then, the temperature control method including the steps from the first plasma processing step (S10) to the second plasma processing step (S40) will be hereinafter described. In the first plasma processing step (S10), the processing temperature is controlled to reach the first temperature (T1). Then, when first photoelectric conversion body 10 is formed, introduction of raw material gas and application of an AC voltage is stopped, and then, the process proceeds to the temperature regulating step (S20). In the temperature regulating step (S20), the processing temperature is lowered to the third temperature (T3) lower than the first temperature (T1) and lower than the second temperature (T2) attained in the second plasma processing step (S40) in the subsequent stage. Then, the process proceeds to the temperature raising step (S30), in which the processing temperature is raised to the second temperature (T2). Then, the proceed proceeds to the second plasma processing step (S40), in which introduction of raw material gas and application of the AC voltage are resumed, and also the processing temperature is controlled so as to reach the second temperature (T2) in this second plasma processing step.

According to the manufacturing method of the present invention, the processing temperature can be regulated by using or not using heating means for heating an anode and, if required, cooling means for cooling an anode. In addition, the expression of “the processing temperature is regulated” in the manufacturing method described in the present specification means that, for example, the heating means and/or the cooling means are/is used such that the processing temperature reaches the control temperature while directly or indirectly detecting the processing temperature (the anode in the present embodiment). In this case, a certain amount of time is required until the processing temperature reaches the same temperature as the control temperature.

When the processing temperature is lowered, the temperature may be lowered by cooling using the cooling means, may be lowered not by using the heating means, or may be lowered by weakening heating by the heating means. Alternatively, the processing temperature can also be lowered by using an appropriate combination of these methods. When the processing temperature is raised, the temperature may be raised by heating using the heating means or by strengthening heating by the heating means, or may be raised not by using the cooling means or by weakening cooling by the cooling means. Alternatively, the processing temperature can also be raised by using an appropriate combination of these methods.

In the present embodiment, the temperature of the anode is controlled only by using the heating means but not using the cooling means.

### Example 1a

According to the manufacturing method of the present embodiment, a photoelectric conversion device was produced on the conditions that the power density per electrode unit in the first plasma processing step (S10) was set at 0.068 W/cm² and the power density per electrode unit in the second plasma processing step (S40) was set at 0.225 W/cm².

FIG. 4 is a graph showing changes in the control temperature and the actual processing temperature from the first plasma processing step (S10) to the second plasma processing step (S40) in the present example. In FIG. 4, the horizontal axis shows time while the vertical axis shows a temperature. In FIG. 4, the alternate long and short dashed line shows a control temperature while the solid line shows an actual processing temperature. The processing temperature, that is, the temperature of an anode, was measured by a thermocouple.

As shown in FIG. 4, the control temperature was set at T1 in the first plasma processing step (S10). When first photoelectric conversion body 10 was formed, introduction of the raw material gas and application of the AC voltage were stopped, and the process proceeded to the temperature regulating step (S20), in which the control temperature was set at T3. At the time when the processing temperature was lowered to the same temperature as T3 equal to the control temperature, the process proceeded to the temperature raising step (S30), in which the control temperature was set at T2. Then, at the time when the processing temperature was raised to the same temperature as T2 equal to the control temperature, the process proceeded to the second plasma processing step (S40), in which introduction of the raw material gas and application of the AC voltage were resumed. In the second plasma processing step (S40), the control temperature was maintained at T2.

The photoelectric conversion device produced in the present example exhibited improved non-uniformity of the in-plane photoelectric conversion characteristics as compared with the photoelectric conversion device produced by the manufacturing method not including the temperature regulating step (S20) and the temperature raising step (S30), thereby achieving photoelectric conversion characteristics equivalent to those of the photoelectric conversion device produced by the manufacturing method using separate reaction chambers for first photoelectric conversion body 10 and second photoelectric conversion body 20. It is considered that this is because the non-uniformity of the in-plane temperature of the product to be processed has been improved in the second plasma processing step (S40) as compared with the case where the temperature regulating step (S20) and the temperature raising step (S30) were not included. As to the degree of the uniformity of the in-plane photoelectric conversion characteristics, a photoelectric conversion device was divided by laser scribing into photoelectric conversion devices each having a relatively smaller area, and the photoelectric conversion characteristics of each divided photoelectric conversion device having a relatively smaller area were compared with the position of each divided photoelectric conversion device having a relatively smaller area within the photoelectric conversion device, thereby evaluating the in-plane uniformity of the photoelectric conversion characteristics.

### Example 1b

According to the manufacturing method of the present embodiment, a photoelectric conversion device was produced on the conditions that the power density per electrode unit in the first plasma processing step (S10) was set at 0.068 W/cm² and the power density per electrode unit in the second plasma processing step (S40) was set at 0.300 W/cm².

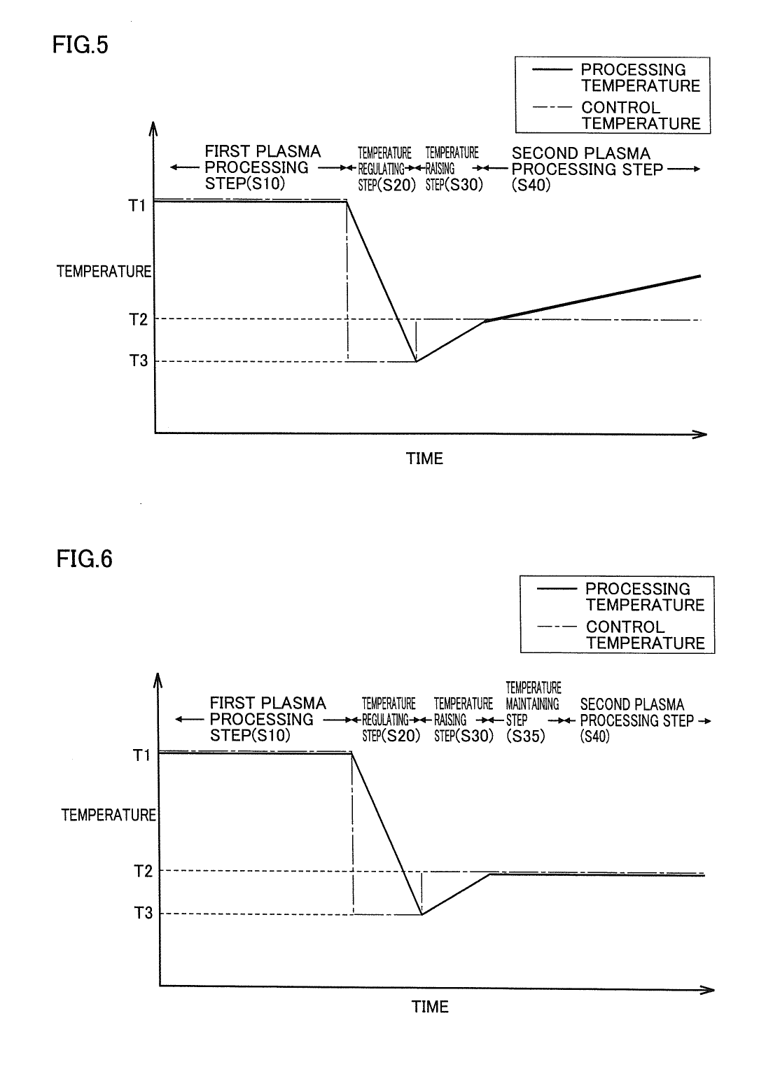

FIG. 5 is a graph showing changes in the control temperature and the processing temperature from the first plasma processing step (S10) to the second plasma processing step (S40) in the present example. In FIG. 5, the alternate long and short dashed line shows a control temperature while the solid line shows an actual processing temperature. The processing temperature, that is, the temperature of an anode, was measured by a thermocouple.

As shown in FIG. 5, in the second plasma processing step (S40), since the power density was relatively high and the substrate was readily heated by radio-frequency discharge, the processing temperature continued to gently rise, but was not changed to come close to the control temperature even if use of the heating means was controlled.

Also in the photoelectric conversion device produced in the present example, the non-uniformity of the in-plane photoelectric conversion characteristics was improved as compared with the photoelectric conversion device produced by the manufacturing method not including the temperature regulating step (S20) and the temperature raising step (S30), thereby achieving the output equivalent to that of the photoelectric conversion device produced by the manufacturing method using separate reaction chambers for first photoelectric conversion body 10 and second photoelectric conversion body 20. It is considered that this is because the processing temperature continues to gently rise in the second plasma processing step (S40), but the in-plane temperature of the product to be processed is uniformly regulated by lowering the processing temperature once in the temperature regulating step (S20).

It is considered that the greater the electric power is in the step of stacking a second photoelectric conversion body, that is, the greater the power density per electrode unit is, the more the in-plane temperature of the product to be processed tends to be nonuniform. However, the results of the present example showed that the non-uniformity of the in-plane photoelectric conversion characteristics is improved also in the above-described case by employing the manufacturing method of the present invention. Therefore, the effect of the present invention is more remarkably achieved when the power density per electrode unit in the second plasma processing step (S40) is as high as 0.225 W/cm² or higher.

### Second Embodiment

In the present embodiment, a plasma CVD device 200 shown in FIG. 2 is used to manufacture a photoelectric conversion device 100 shown in FIG. 3 by the manufacturing method according to the present invention.

The manufacturing method of the present embodiment is different from that of the first embodiment only in that a temperature maintaining step (S35) is included between the temperature raising step (S30) and the second plasma processing step (S40). In the present embodiment, at the time when the processing temperature reaches the second temperature (T2), the process proceeds to the temperature maintaining step (S35), in which the control temperature set at the second temperature (T2) is maintained for a certain period of time. Then, the process proceeds to the second plasma processing step (S40), in which introduction of raw material gas and application of AC power are resumed, and the control temperature is set at the second temperature (T2) in this second plasma processing step.

In the present embodiment, the temperature of the anode is controlled only by using the heating means but not using the cooling means.

### Example 2

According to the manufacturing method of the present embodiment, a photoelectric conversion device was produced on the conditions that the power density per electrode unit in the first plasma processing step (S10) was set at 0.068 W/cm² and the power density per electrode unit in the second plasma processing step (S40) was set at 0.225 W/cm².

FIG. 6 is a graph showing changes in the control temperature and the actual processing temperature from the first plasma processing step (S10) to the second plasma processing step (S40) in the present example. In FIG. 6, the alternate long and short dashed line shows a control temperature while the solid line shows a processing temperature. The processing temperature, that is, the temperature of an anode, was measured by a thermocouple.

As shown in FIG. 6, unlike Example 1, at the time when the processing temperature reached the second temperature (T2) in the temperature raising step (S30), the process proceeded to the temperature maintaining step (S35), in which the control temperature set at the second temperature (T2) was maintained for a certain period of time. Then, the process proceeded to the second plasma processing step (S40), in which introduction of raw material gas and application of an AC voltage were resumed, and the control temperature was set at the second temperature (T2) in this second plasma processing step.

The photoelectric conversion device produced in the present example exhibited further improved non-uniformity of the in-plane photoelectric conversion characteristics as compared with that in Example 1.

(Experiment for Evaluating Optimum Range of Third Temperature (T3))

By the manufacturing method similar to that in Example 2, a plurality of photoelectric conversion devices were manufactured on the conditions that the first temperature (T1) and the second temperature (T2) were fixed and only the third temperature (T3) was changed. Then, the output of each photoelectric conversion device and the time of the temperature raising step (S30) were measured.

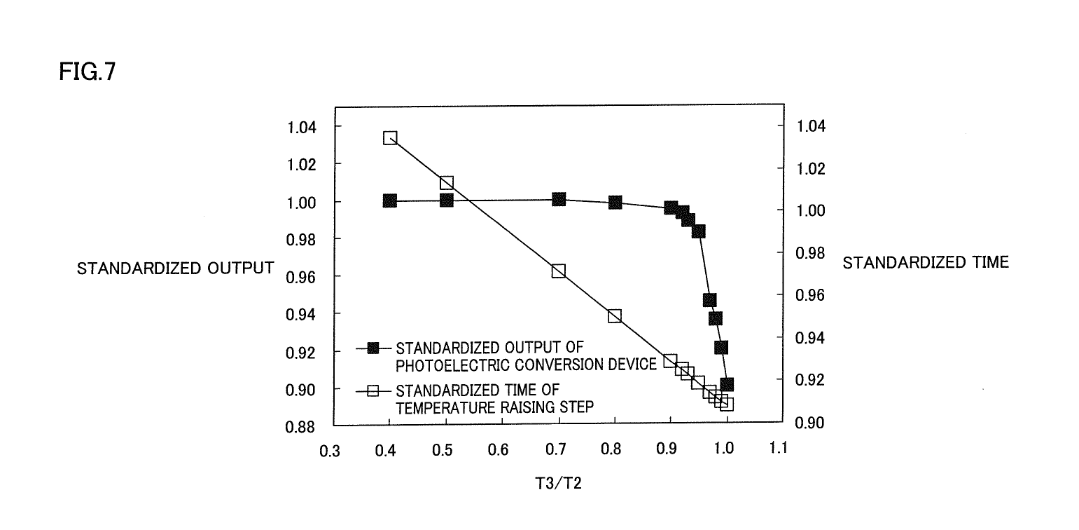

FIG. 7 shows the relation between the third temperature (T3) and each of the output of the photoelectric conversion device and the time required for forming the second photoelectric conversion body in the manufacturing step. In FIG. 7, the horizontal axis shows the value obtained by dividing the centigrade temperature value of the third temperature (T3) by the centigrade temperature value of the second temperature (T2) (which will be represented as “T3/T2” for convenience). The vertical axis shows the standardized output of the photoelectric conversion device and the standardized time of the temperature raising step (S30).

As can be seen from FIG. 7, the output of the photoelectric conversion device was improved in accordance with a decrease in the third temperature until T3/T2 reached approximately 0.7, but even if T3/T2 becomes lower than that, a significant effect of improving the output was not exhibited. On the other hand, the time of the temperature raising step (S30) was lengthened as the third temperature lowers. As described above, for the purpose of achieving excellent output characteristics while improving the efficiency in the manufacturing time period, T3/T2 preferably falls within the range of 0.7 to 0.99, and further preferably falls within the range of 0.85 to 0.95.

### Third Embodiment

According to the present embodiment, plasma CVD device 200 shown in FIG. 2 is used to manufacture photoelectric conversion device 100 shown in FIG. 3 by the manufacturing method according to the present invention.

The manufacturing method of the present embodiment is different from that of the second embodiment only in that the cooling means is used to cool a substrate in the temperature regulating step (S30) and the second plasma processing step (S40). According to the present embodiment, a circulation pipe line through which nitrogen gas flows as a coolant is provided as the cooling means within anode 223 in which a product to be processed is disposed. The temperature of nitrogen gas is regulated on the outside of reaction chamber 220. By such the cooling means, anode 223 can be entirely cooled while the product to be processed in contact therewith can be cooled.

### Example 3

According to the manufacturing method of the present embodiment, a photoelectric conversion device was produced on the conditions that the power density per electrode unit in the first plasma processing step (S10) was set at 0.068 W/cm² and the power density per electrode unit in the second plasma processing step (S40) was set at 0.225 W/cm².

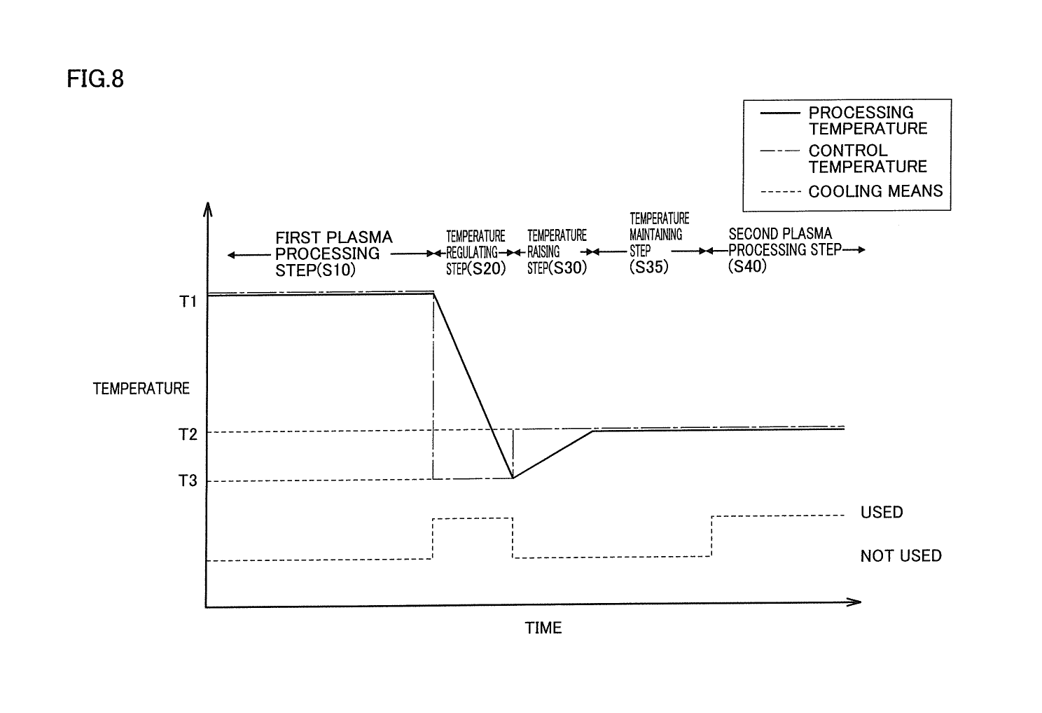

FIG. 8 is a graph showing changes in the control temperature and the processing temperature from the first plasma processing step (S10) to the second plasma processing step (S40) in the present example. In FIG. 8, the alternate long and short dashed line shows a control temperature; the solid line shows a processing temperature; and the dotted line shows whether the cooling means is used or not used. The processing temperature, that is, the temperature of an anode, was measured by a thermocouple. Furthermore, the state where nitrogen as a coolant circulates through the cooling means was defined as “used” while the state where at least a part of the circulation channel is interrupted in the cooling means and nitrogen as a coolant does not circulate therethrough was defined as “not used”.

In the photoelectric conversion device produced in the present example, the non-uniformity of the in-plane photoelectric conversion characteristics was improved to the same degree as that in Example 2, and further, the time required for the temperature regulating step (S20) was shortened as compared with Example 2.

In the temperature regulating step (S20) of the present example, the time required for lowering the processing temperature to the third temperature (T3) (the time of the temperature regulating step (S20)) can be shortened by using the cooling means. However, it is expected that the uniformity of the in-plane temperature of the product to be processed is reduced as the time of the temperature regulating step (S20) is shortened. It is considered that, in the present example, the temperature raising step (S30) and the temperature maintaining step (S35) not using the cooling means are included, thereby improving the non-uniformity of the in-plane temperature of the product to be processed, so that excellent photoelectric conversion characteristics can be achieved.

### Fourth Embodiment

According to the present embodiment, plasma CVD device 200 shown in FIG. 2 is used to manufacture photoelectric conversion device 100 shown in FIG. 3 by the manufacturing method according to the present invention.

The manufacturing method of the present embodiment is different from that of the third embodiment only in that the control temperature in the first plasma processing step (S10) is changed from the first temperature (T1) to the third temperature (T3) after a lapse of an optional time period, and that the cooling means is used also in the first plasma processing step (S10) from this point of time at which the control temperature is changed. According to the present embodiment, in the first plasma processing step (S10), the control temperature is lowered at the time when no influence is exerted upon the characteristics of first photoelectric conversion body 10 (after a lapse of an optional time period), and also the cooling means is used, with the result that the time of the temperature regulating step (S20) can be shortened.

### Example 4

According to the manufacturing method of the present embodiment, a photoelectric conversion device was produced on the conditions that the power density per electrode unit in the first plasma processing step (S10) was set at 0.068 W/cm² and the power density per electrode unit in the second plasma processing step (S40) was set at 0.225 W/cm².

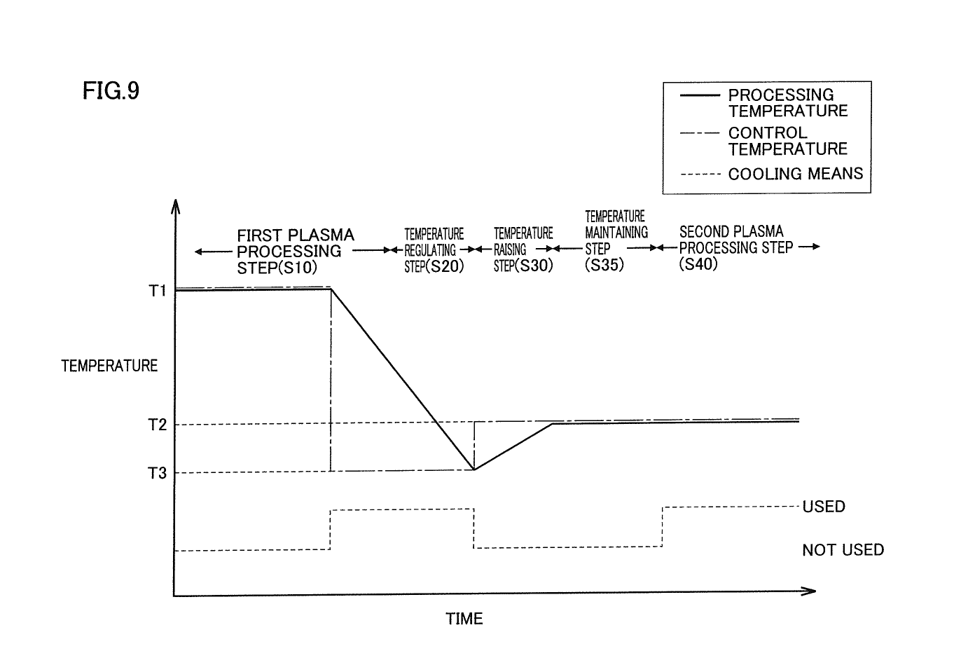

FIG. 9 is a graph showing changes in the control temperature and the processing temperature from the first plasma processing step (S10) to the second plasma processing step (S40) in the present example. In FIG. 9, the alternate long and short dashed line shows a control temperature; the solid line shows a processing temperature; and the dotted line shows whether the cooling means is used or not used. The processing temperature, that is, the temperature of an anode, was measured by a thermocouple. Furthermore, the state where nitrogen as a coolant circulates through the cooling means was defined as “used” while the state where at least a part of the circulation channel is interrupted in the cooling means and nitrogen as a coolant does not circulate therethrough was defined as “not used”.

In the photoelectric conversion device produced in the present example, the non-uniformity of the in-plane photoelectric conversion characteristics was improved to the same degree as that in Example 2, and the time required for the temperature regulating step (S20) was shortened as compared with that in Example 3.

In addition, it is expected that the uniformity of the in-plane temperature of the product to be processed is reduced as the time of the temperature regulating step (S20) is shortened. It is considered that, in the present example, the temperature raising step (S30) and the temperature maintaining step (S35) not using the cooling means are included, thereby improving the non-uniformity of the in-plane temperature of the product to be processed, so that excellent photoelectric conversion characteristics can be achieved.

### Fifth Embodiment

According to the present embodiment, plasma CVD device 200 shown in FIG. 2 is used to manufacture photoelectric conversion device 100 shown in FIG. 3 by the manufacturing method according to the present invention.

The manufacturing method of the present embodiment is different from that of the third embodiment only in that the cooling means is used not in the entire second plasma processing step (S40) but used only in the case where the power density per unit area is equal to or greater than a prescribed value. The prescribed value can be set at 0.180 W/cm², for example. When the time period of using the cooling means in the second plasma processing step (S40) is reduced to a relatively short time period, the in-plane temperature of the product to be processed can be prevented from becoming nonuniform by the cooling means while preventing overheating of the product to be processed.

When the time period of using the cooling means is increased, the difference in the product to be processed between the heat input by radio-frequency discharge and the releasing heat by the cooling means is increased. Thus, it is expected that the in-plane temperature distribution of the product to be processed significantly deteriorates. However, by controlling use of the cooling means as in the present embodiment, the in-plane temperature of the product to be processed can be prevented from becoming nonuniform.

### Example 5

According to the manufacturing method of the present embodiment, a photoelectric conversion device was produced on the conditions that the power density per electrode unit in the first plasma processing step (S10) was set at 0.068 W/cm²; and the power density per electrode unit in the second plasma processing step (S40) was set at 0.180 W/cm² when forming second p-type semiconductor layer 21, set at 0.225 W/cm² when forming i-type microcrystalline silicon-based photoelectric conversion layer 22, and set at 0.140 W/cm² when forming second n-type semiconductor layer 23.

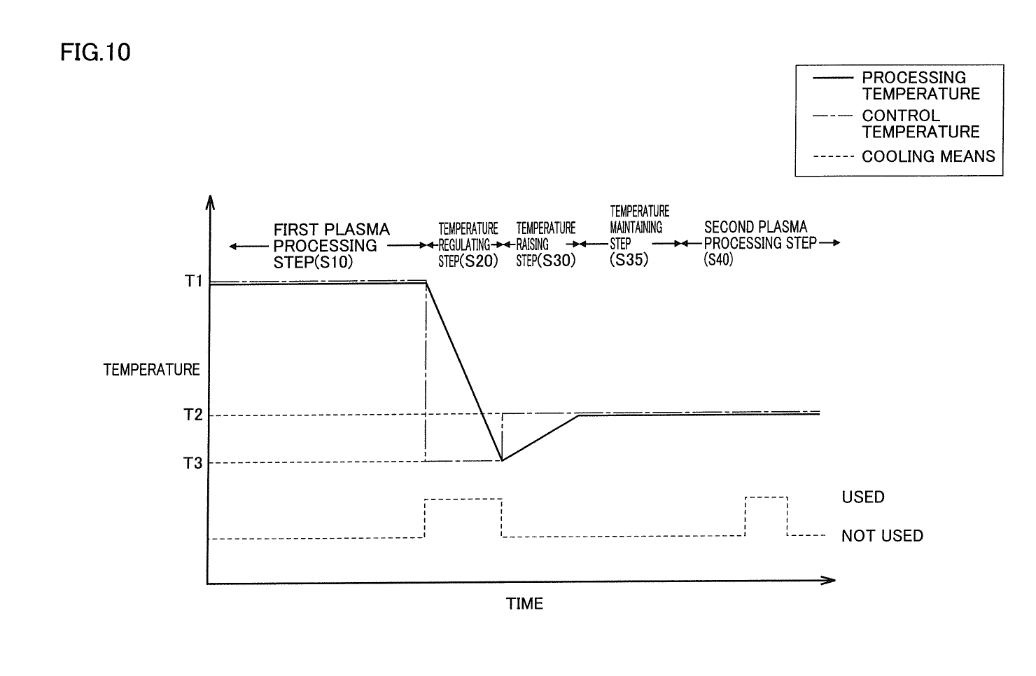

FIG. 10 is a graph showing changes in the control temperature and the processing temperature from the first plasma processing step (S10) to the second plasma processing step (S40) in the present example. In FIG. 10, the alternate long and short dashed line shows a control temperature; the solid line shows a processing temperature; and the dotted line shows whether the cooling means is used or not used. The processing temperature, that is, the temperature of an anode, was measured by a thermocouple. Furthermore, the state where nitrogen as a coolant circulates through the cooling means was defined as “used” while the state where at least a part of the circulation channel is interrupted in the cooling means and nitrogen as a coolant does not circulate therethrough was defined as “not used”. In the second plasma processing step (S40), the cooling means was used only at the time when forming i-type microcrystalline silicon-based photoelectric conversion layer 22 having power density per electrode unit of 0.180 W/cm² or more.

In the photoelectric conversion device produced in the present example, the non-uniformity of the in-plane photoelectric conversion characteristics was improved as compared with Example 4.

### Sixth Embodiment

According to the present embodiment, plasma CVD device 200 shown in FIG. 2 is used to manufacture photoelectric conversion device 100 shown in FIG. 3 by the manufacturing method according to the present invention.

The manufacturing method of the present embodiment is different from that of the third embodiment only in that a stacked body is removed from within the reaction chamber after the second plasma processing step (S40), and then the third plasma processing step (S50) is carried out. In the third plasma processing step (S50), the inside of the reaction chamber is cleaned by plasma processing. The control temperature in the third plasma processing step (S50) is set at a temperature different from the control temperature in the second plasma processing step (S40). In the present embodiment, the control temperature in the third plasma processing step (S50) is set at a fourth temperature (T4) higher than the third temperature (T3) that is the control temperature in the second plasma processing step (S40). Furthermore, in the third plasma processing step (S50), the cooling means is used continuously subsequent to the second plasma processing step (S40) until a lapse of an optional time period, and after that, the cooling means is not used. In this way, since the inside of the reaction chamber can be cleaned by including the third plasma processing step (S50), the first plasma processing step (S10), the temperature regulating step (S20), the temperature raising step (S30), and the second plasma processing step (S40) can be repeatedly carried out. Also, the influence of impurities can be suppressed even if these steps are repeatedly carried out.

### Example 6

According to the manufacturing method of the present embodiment, a photoelectric conversion device was produced on the conditions that the power density per electrode unit in the first plasma processing step (S10) was set at 0.068 W/cm² and the power density per electrode unit in the second plasma processing step (S40) was set at 0.225 W/cm². The power density per electrode unit in the third plasma processing step (S50) was set at 0.320 W/cm².

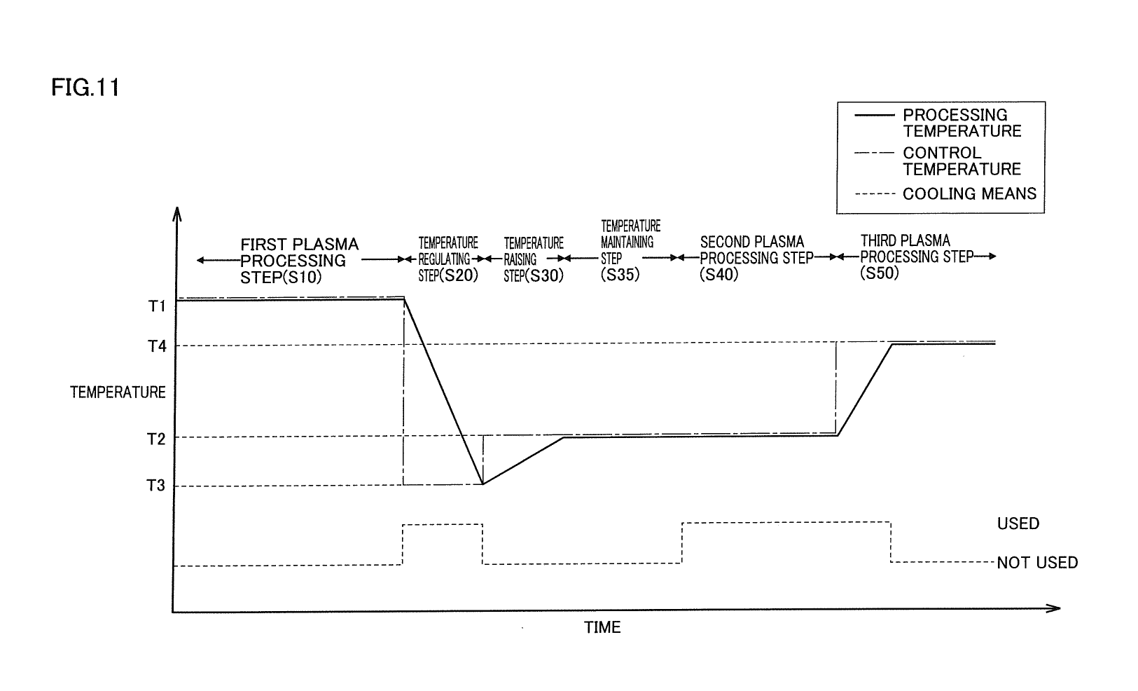

FIG. 11 is a graph showing changes in the control temperature and the processing temperature from the first plasma processing step (S10) to the third plasma processing step (S50) in the present example. In FIG. 11, the alternate long and short dashed line shows a control temperature; the solid line shows a processing temperature; and the dotted line shows whether the cooling means is used or not used. The processing temperature, that is, the temperature of an anode, was measured by a thermocouple. Furthermore, the state where nitrogen as a coolant circulates through the cooling means was defined as “used” while the state where at least a part of the circulation channel is interrupted in the cooling means and nitrogen as a coolant does not circulate therethrough was defined as “not used”.

According to the photoelectric conversion device produced in the present example, the non-uniformity of the in-plane photoelectric conversion characteristics was improved to the same degree as that in Example 2. Furthermore, also when the steps from the first plasma processing step (S10) to the second plasma processing step (S40) were again carried out after the third plasma processing step (S50) to produce another stacked body, a photoelectric conversion device having photoelectric conversion characteristics comparable to those of the first stacked body could be achieved.

### REFERENCE SIGNS LIST

1 substrate, 2 transparent conductive film, 3 conductive film, 4 metal electrode, 10 first photoelectric conversion body, 11 first p-type semiconductor layer, 12 i-type amorphous silicon-based photoelectric conversion layer, 13 first n-type semiconductor layer, 20 second photoelectric conversion body, 21 second p-type semiconductor layer, 22 i-type microcrystalline silicon-based photoelectric conversion layer, 23 second n-type semiconductor layer, 100 photoelectric conversion device, 200 plasma CVD device, 220 reaction chamber, 222 cathode, 223 anode.

1. A method of manufacturing a photoelectric conversion device for forming a semiconductor layer on a substrate by a plasma CVD method, said method comprising:
a first plasma processing step in which a processing temperature reaches a first temperature;
a second plasma processing step in which said processing temperature reaches a second temperature; and
a temperature regulating step of lowering said processing temperature to a third temperature lower than the first temperature and the second temperature after said first plasma processing step and before said second plasma processing step,
said first plasma processing step, said temperature regulating step and said second plasma processing step being carried out within the same reaction chamber.

2. The method of manufacturing a photoelectric conversion device according to claim 1, said photoelectric conversion device being formed by stacking a substrate, a first photoelectric conversion body and a second photoelectric conversion body in this order, wherein
said first photoelectric conversion body is stacked in said first plasma processing step, and
said second photoelectric conversion body is stacked in said second plasma processing step.

3. The method of manufacturing a photoelectric conversion device according to claim 2, wherein
said first photoelectric conversion body includes an amorphous silicon-based photoelectric conversion layer, and
said second photoelectric conversion body includes a microcrystalline silicon-based photoelectric conversion layer.

4. The method of manufacturing a photoelectric conversion device according to claim 1, wherein said third temperature has a value, as a centigrade temperature, obtained by multiplying a centigrade temperature value of said second temperature by 0.7 to 0.99.

5. The method of manufacturing a photoelectric conversion device according to claim 1, wherein said processing temperature is regulated by using heating means for heating an inside of said reaction chamber and/or cooling means for cooling the inside of said reaction chamber.

6. The method of manufacturing a photoelectric conversion device according to claim 5, wherein said first plasma processing step includes a time during which said cooling means is not used.

7. The method of manufacturing a photoelectric conversion device according to claim 5, wherein said second plasma processing step includes a time during which said cooling means is not used.

8. The method of manufacturing a photoelectric conversion device according to claim 1, further comprising a temperature raising step of raising said processing temperature from the third temperature to the second temperature after said temperature regulating step, wherein
at least a part of said temperature raising step is carried out during said second plasma processing step.

9. The method of manufacturing a photoelectric conversion device according to claim 8, wherein
said processing temperature is regulated by using the heating means for heating the inside of said reaction chamber and/or the cooling means for cooling the inside of said reaction chamber, and
said cooling means is not used in said temperature raising step.

10. The method of manufacturing a photoelectric conversion device according to claim 1, further comprising a temperature maintaining step of maintaining said processing temperature at said second temperature for a certain period of time before said second plasma processing step.

11. The method of manufacturing a photoelectric conversion device according to claim 10, wherein
said processing temperature is regulated by using the heating means for heating the inside of said reaction chamber and/or the cooling means for cooling the inside of said reaction chamber, and
said cooling means is not used in said temperature maintaining step.

12. The method of manufacturing a photoelectric conversion device according to claim 1, further comprising a third plasma processing step in which said processing temperature reaches a fourth temperature different from said second temperature after said second plasma processing step, wherein
said first plasma processing step, said temperature regulating step, said second plasma processing step, and said third plasma processing step are carried out within the same reaction chamber.

13. The method of manufacturing a photoelectric conversion device according to claim 12, wherein the inside of said reaction chamber is cleaned in said third plasma processing step.

14. The method of manufacturing a photoelectric conversion device according to claim 12, wherein
said processing temperature is regulated by using the heating means for heating the inside of said reaction chamber and/or the cooling means for cooling the inside of said reaction chamber, and
said cooling means is used in said third plasma processing step.

15. The method of manufacturing a photoelectric conversion device according to claim 14, wherein said third plasma processing step includes a time during which said cooling means is not used.

16. The method of manufacturing a photoelectric conversion device according to claim 1, wherein said first plasma processing step, said temperature regulating step and said second plasma processing step are repeatedly carried out within the same reaction chamber.
